(19) United States
(12) Patent Application Publication
(10) Pub. No.: US 2010/0148337 A1
(43) Pub. Date: Jun. 17, 2010

(54) STACKABLE SEMICONDUCTOR PACKAGE AND PROCESS TO MANUFACTURE SAME

(76) Inventors: Yong Liu, Scarborough, ME (US); Luke England, Portland, ME (US); Howard Allen, Limington, ME (US)

Correspondence Address: HISCOCK & BARCLAY, LLP, 2000 HSBC PLAZA, 100 Chestnut Street, ROCHESTER, NY, 14604-2404, US

(21) Appl. No.: 12/336,633

(22) Filed: Dec. 17, 2008

(51) Int. Cl. H01L 23/48; H05K 7/00; H01L 21/02

(52) U.S. Cl. 257/686; 361/735; 438/109; 257/E21.002; 257/E23.142

(57) ABSTRACT

In one form a stackable electrical device package has a first plurality of traces, the electrical device bonded to at least some of the first plurality of traces, a second plurality of vertical posts attached to the first plurality of traces, and encapsulation material enclosing the electrical device and sides of the first plurality of traces and the second plurality of vertical posts such that bottoms of the first plurality of traces are exposed on the bottom of the semiconductor package, and tops of the vertical posts are exposed on the top of the semiconductor package. In another form a multiple electrical device package has a semiconductor device in a wafer having a plurality of contacts on an upper surface of the wafer, a first plurality of traces attached to the top of the wafer, a second plurality of vertical posts attached to the first plurality of traces, an electrical device bonded to at least some of the first plurality of traces, and encapsulation material enclosing the electrical device and sides of the first plurality of traces and the second plurality of vertical posts such that tops of the vertical posts are exposed on the top of the semiconductor package.

### FIELD OF THE INVENTION

This invention relates to packages for semiconductor devices, and more particularly, to stackable packages for semiconductor devices.

### BACKGROUND OF THE INVENTION

As the density of semiconductor devices increases, the connections to the devices also become more dense, and the spacing between electrical contacts on a die are much smaller than the spacing on die interconnecting media such as printed circuit boards. The package for such semiconductor die therefore has to expand the spacing between adjacent connections to the die in a compact package that can be handled by an original equipment manufacturer (OEM). In the past metallic lead frames have been used to secure the die and to provide leads that interconnect the die to patterns which can be formed on the interconnecting media. A goal of the packaging industry is to minimize the amount of lead material needed while ensuring the integrity of the package using processes that are cost effective, and also to minimize product footprint through the use of three dimensional packaging methods that result in higher density functionality in a smaller surface area.

### SUMMARY OF THE INVENTION

The invention comprises, in one form thereof, a stackable electrical device package having a first plurality of traces, the electrical device bonded to at least some of the first plurality of traces, a second plurality of vertical posts attached to the first plurality of traces, and encapsulation material enclosing the electrical device and sides of the first plurality of traces and sides of the second plurality of vertical posts such that bottoms of the first plurality of traces are exposed on the bottom of the semiconductor package, and tops of the vertical posts are exposed on the top of the semiconductor package.

The invention comprises, in another form thereof, a multiple electrical device package comprising a semiconductor device in a wafer having a plurality of contacts on an upper surface of the wafer, a first plurality of traces attached to the top of the wafer, a second plurality of vertical posts attached to the first plurality of traces, an electrical device bonded to at least some of the first plurality of traces, and encapsulation material enclosing the electrical device and sides of the first plurality of traces and sides of the second plurality of vertical posts such that tops of the vertical posts are exposed on the top of the semiconductor package.

In yet another form, the invention includes a method for forming a stackable electrical device package. The method comprises the steps of forming a first plurality of traces on a sacrificial wafer, forming a second plurality of vertical posts on the first plurality of traces, attaching the electrical device to at least some of the first plurality of traces, and encapsulating the electrical device and sides of the first plurality of traces and sides of the second plurality of vertical posts and removing the sacrificial wafer such that bottoms of the first plurality of traces are exposed on the bottom of the semiconductor package, and tops of the vertical posts are exposed on the top of the semiconductor package.

In still another form, the invention includes a method for forming a multiple electrical device package. The method comprises the steps of forming a first plurality of traces on a semiconductor wafer having a second plurality of contacts on an upper surface of the wafer, wherein at least some of the first plurality of traces are attached to at least some of the second plurality of contacts, forming a third plurality of vertical posts on the first plurality of traces, attaching an electrical device to at least some of the first plurality of traces, and encapsulating the electrical device and sides of the first plurality of traces and sides of the second plurality of vertical posts such that tops of the vertical posts are exposed on the top of the semiconductor package.

### BRIEF DESCRIPTION OF THE DRAWINGS

The aforementioned and other features, characteristics, advantages, and the invention in general will be better understood from the following more detailed description taken in conjunction with the accompanying drawings, in which:

FIGS. 1A, 1B, 1C, 1D, 1E, 1F, and 1G are side diagrammatical views of selected processing steps according to one embodiment of the present invention;

FIGS. 2A and 2B are side diagrammatical views of stacked semiconductor packages, some of which are the same as the packages shown in FIG. 1G and some of which are similar to the packages shown in FIG. 1G;

FIGS. 3A and 3B are respective top and bottom isometric views of an embodiment of a package which can be made using the processing steps shown in FIGS. 5A-1G;

FIGS. 4A, 4B, 4C, 4D, 4E, 4F, and 4G are side diagrammatical views of selected processing steps according to another embodiment of the present invention; and

FIGS. 5A and 5B are respective top and bottom isometric views of an embodiment of a package which can be made using the processing steps shown in FIGS. 3A-3G.

It will be appreciated that for purposes of clarity and where deemed appropriate, reference numerals have been repeated in the figures to indicate corresponding features. Also, the relative size of various objects in the drawings has in some cases been distorted to more clearly show the invention.

### DETAILED DESCRIPTION

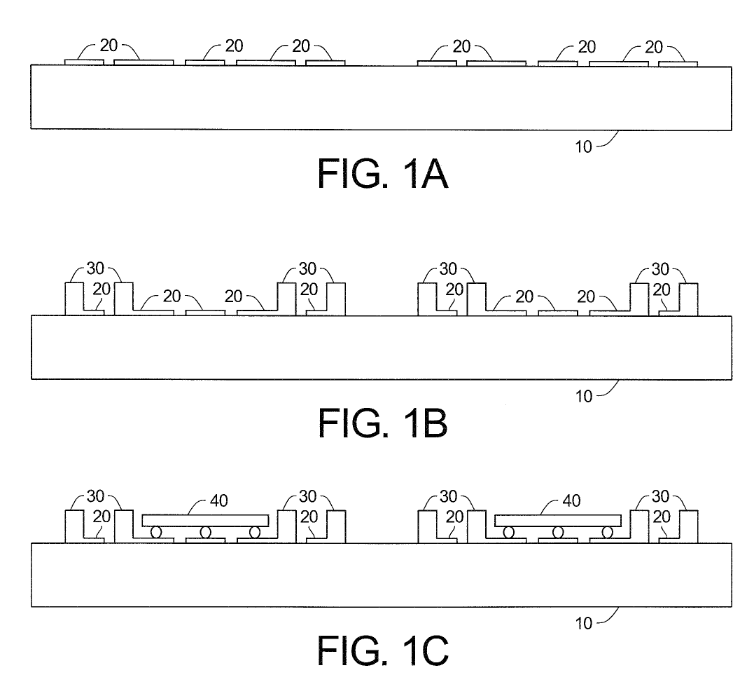

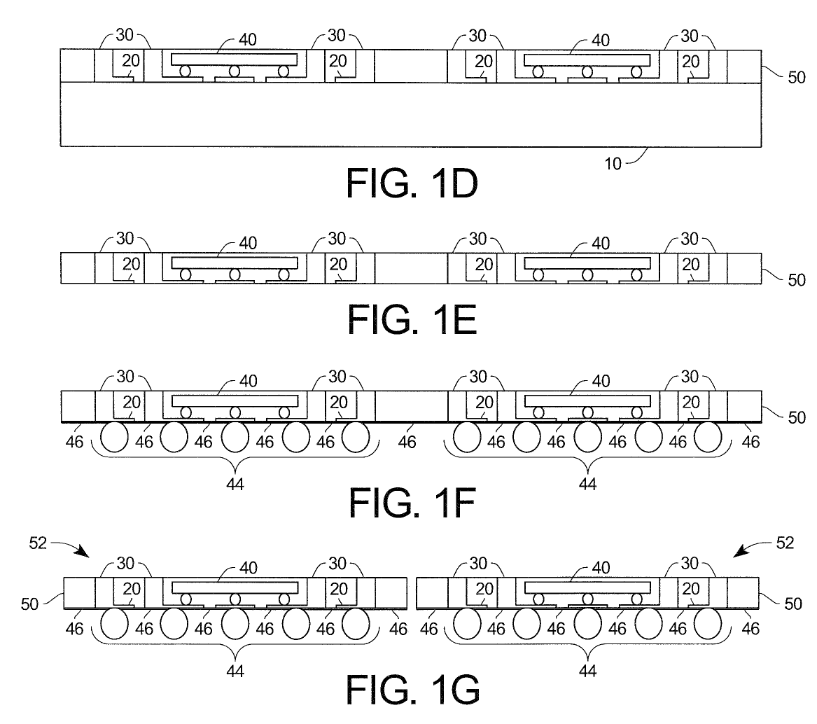

Turning now to the drawings, FIG. 1A is a side diagrammatical view of a sacrificial wafer 10 with a plurality of copper patterns 20 formed thereon. The sacrificial wafer 10 is a carrier substrate and may be a low grade silicon wafer. The top surface of the sacrificial wafer 10 may be prepared by backgrinding or polishing to provide a strong adhesive surface for copper patterns or traces 20. The copper traces 20 may be formed by first sputtering copper onto the sacrificial wafer 10 to form a seed layer. Photoresist is applied and patterned to the desired trace structure for the copper traces 20. Additional copper is electroplated onto the patterned seed copper with the photoresist in place. The photoresist is then removed and a shallow etch of the copper is performed to reduce the height of the copper by the slightly more than the height of the seed layer such that relatively thick copper traces 20, having a preferred range of 20 μm to 50 μm thick, are left in one embodiment of the invention.

Copper posts 30 are then formed on at least some of the copper traces 20 as shown in FIG. 1B by laying down another patterned photoresist resist followed by another plating operation. In one embodiment the copper posts are plated to a height of about 200 μm.

Packaged electrical devices such as a semiconductor die 40 are then attached to selected copper traces 20 which form die sites as shown in FIG. 1C. The packaged electrical devices may be other than semiconductor dies, for example packaged passive electrical devices or hybrid integrated circuits. A variety of methods can be used to attached the die to the selected copper traces 20 including, but not limited to, solder bumps or wire stud bumps. Only three of the copper traces 20 shown in FIG. 1C are connected to the semiconductor die 40.

The sides of the copper traces 20 and the sides of the copper posts 30 are then encapsulated along with the semiconductor die 40 using an encapsulating material, such as epoxy molding compound, to form the encapsulation layer 50, as shown in FIG. 1D. The encapsulation can be performed using a variety of methods, including, but not limited to, compression molding and film assist molding. The encapsulation material can act as the die underfill. Alternatively, other underfill techniques may be used prior to encapsulation The encapsulation layer 50 and the copper posts 30 are then planarized. One method for performing the planarization is to use an automated planarization tool made by the Disco Corporation of Tokyo, Japan. Alternatively, standard backgrinding may be used.

The sacrificial wafer 10 is then removed as shown in FIG. 1E. Backgrinding, which may be used to remove sacrificial wafer 10, also removes roughly one half of the thickness of the copper traces 20 to expose the copper traces 20 for surface mounting.

Solder ball arrays 44 may be formed on the bottom of the copper traces 20 as shown in FIG. 1F and may require application of a solder mask 46. Alternatively, the copper traces 20 may be used without additional processing to form a Quad Flat No Lead (QFN) or Land Grid Array (LGA) layout.

FIG. 1G shows the completed packages 52 after singulation.

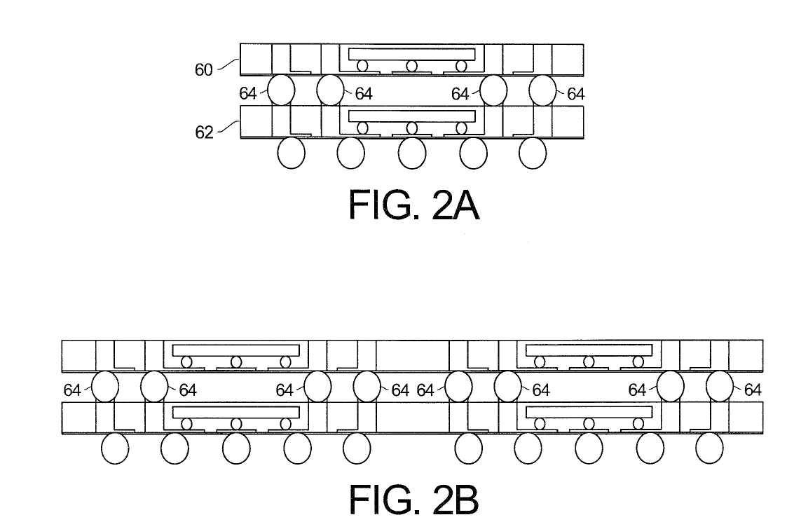

FIG. 2A is a side diagrammatical view of two stacked packages, an upper package 60 and a lower package 62 attached to the upper package 60. The lower package 62 is one of the singulated packages 52 shown in FIG. 1A, while the upper package 60 is similar to one of the packages 52. The four outer solder bumps 64 of the solder ball array 44 have been attached to their respective copper traces 20 to line up with the copper posts 30 in the lower package 62, and the middle solder bump in the packages 52 shown in FIG. 1G is not present since there is not a copper post in the top of the lower package 62.

The top stacked package does not need to be the same as the bottom stacked package 62, it only needs to have interconnect pads that line up with at least some of the posts 30 of the bottom stacked package 62. For example, the top stacked package could be a conventional BGA package, or a passive device such as a capacitor or an inductor. In addition, two or more packages could be stacked on the bottom package 62.

Depending on the package stacking process that is used, the stacking may also be performed in wafer form prior to singulation as shown in FIG. 2B. This may include wafer-to-wafer or die/package-to-wafer processes.

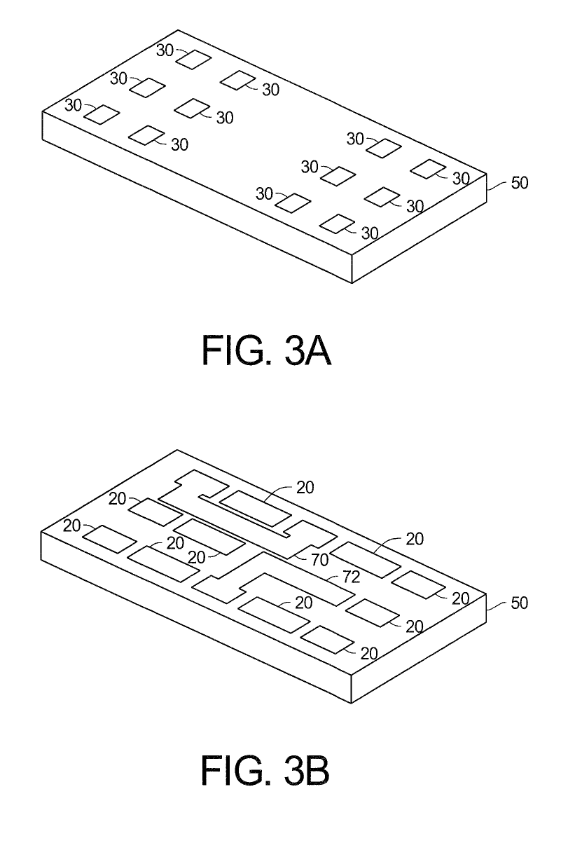

FIGS. 3A and 3B are respective top and bottom perspective views of an embodiment of the package 52. To show the interconnections on the bottom of the package 52 the solder ball array 44 and the solder mask 46 are not shown in FIG. 3B. There are three identical rows in the embodiment shown in FIGS. 3A and 3B, although the number of rows depends on the specific package, and the rows do not have to be identical. In FIG. 3B interconnections 70 and 72 provide connections between two of the copper traces 20 (interconnection 70) and three of the copper traces 20 (interconnection 72) shown in FIG. 1B and their corresponding copper posts 30. The interconnections 70, 72 are formed when the copper traces 20 are formed. Those skilled in the art will recognize that many different interconnection patterns can be made using the copper traces 20 in addition to those shown in FIG. 3B.

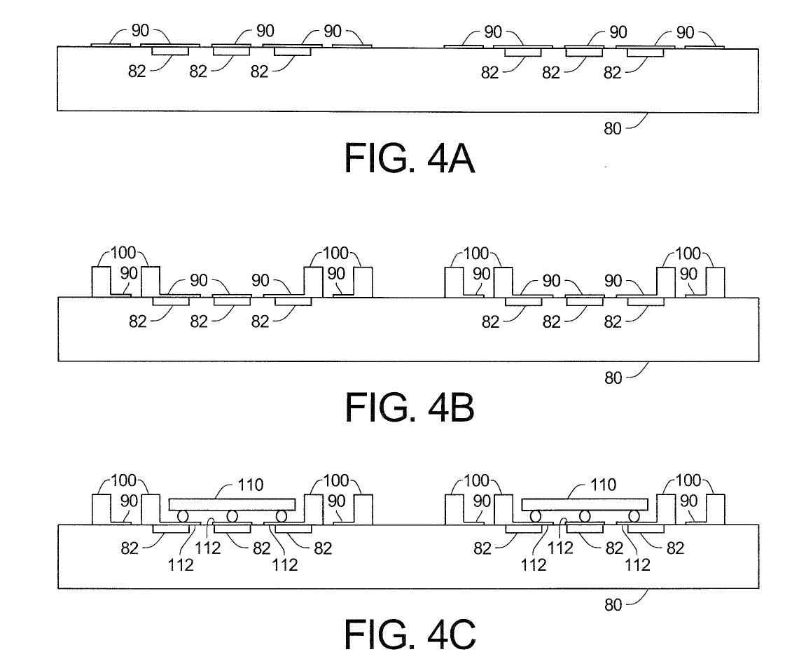

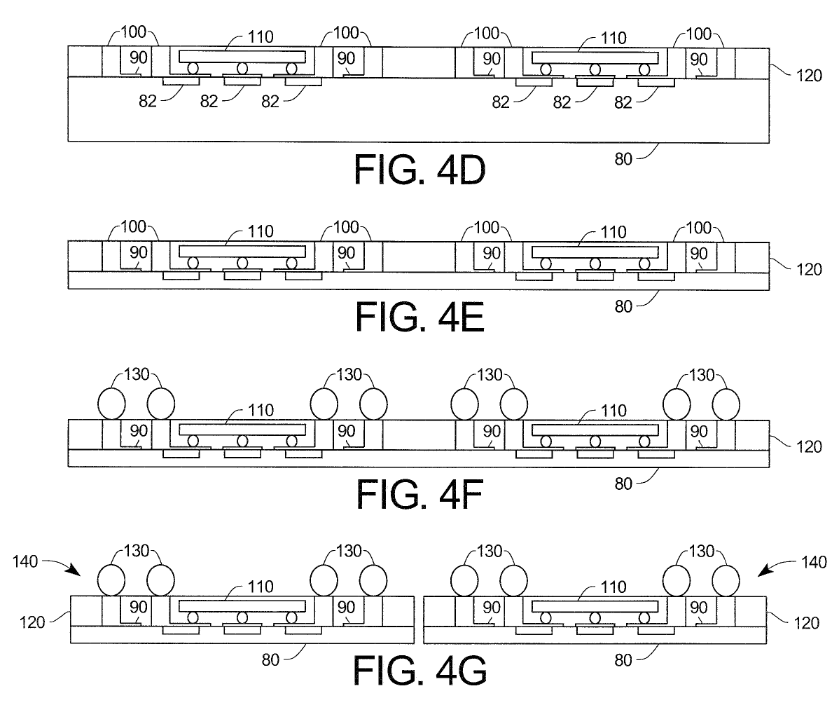

FIGS. 4A, 4B, 4C, 4D, 4E, 4F, and 4G are side diagrammatical views of selected processing steps according to another embodiment of the present invention. As shown in FIG. 4A an active carrier wafer 80 with active devices formed therein has at least three contact regions 82 for each of the active devices in the embodiment shown in FIG. 4A. As will be understood by those skilled in the art the active devices may be diodes having only two contacts or may be any other active devices such as transistors or an integrated circuits which would have many contact regions 82. The active carrier wafer 80 may be planarized, rinsed, and plasma cleaned. Copper traces 90 are formed on the active sacrificial wafer 80 as also shown in FIG. 4A. The copper traces 90 may be formed in the same manner as the copper traces 20 are formed as described above, although the copper traces 90 may be thinner than the copper traces 20 since the traces 90 will not be subjected to a planarization operation or a backgrinding operation as in the case of the copper traces 20. In another embodiment, the traces 90 may be aluminum or another metal rather than copper.

Copper posts 100 are formed on at least some of the copper traces 90 as shown in FIG. 4B. The copper posts 100 may be formed in the same manner as the copper posts 30 shown in FIG. 1B. Packaged electrical devices such as a semiconductor die 110 are then attached to selected copper traces 112 which form die sites as shown in FIG. 4C. The semiconductor die 110 may be attached using one of the methods described above for attaching the semiconductor die 40.

The sides of the copper traces 90 and the sides of the copper posts 100 are then encapsulated along with the semiconductor die 110 using an encapsulating material to form an encapsulation layer 120 as shown in FIG. 4D. The encapsulation process may be performed in the manner described above. The encapsulation layer 120 and the copper posts 100 are then planarized. The planarization may be performed using one of the methods described above in the description of FIG. 1D. The active carrier wafer 80 is then thinned to a desired thickness using one of the methods well known in the art to form the structure shown in FIG. 4E.

Solder balls 130 are then formed on at least some of the copper posts 100 as shown in FIG. 4F. The solder balls 130 may be formed using methods such as, but not limited to, ball drop or a stencil printing. The active carrier wafer 80 and encapsulation layer 120 is then singulated to form the individual packages 140 shown in FIG. 4G.

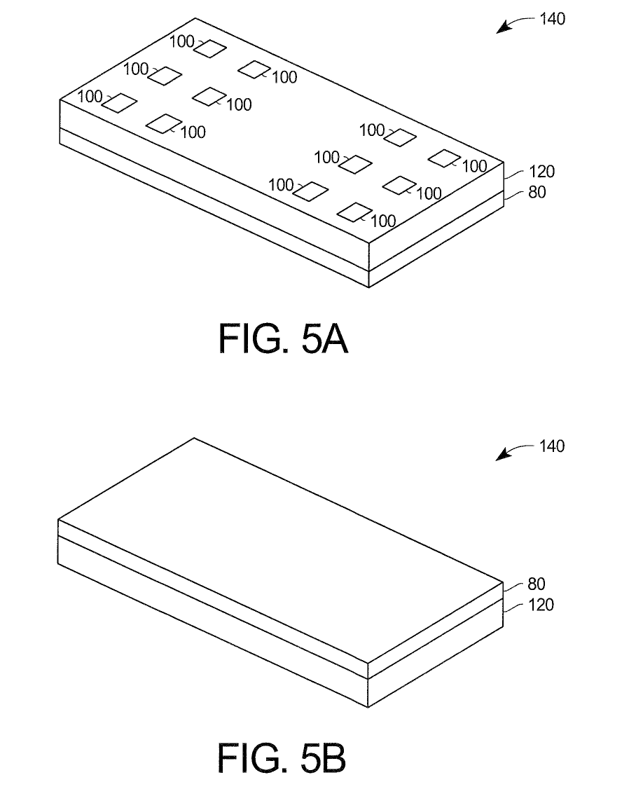

FIGS. 5A and 5B are respective top and bottom perspective views of an embodiment of the package 140. There are three identical rows in the embodiment shown in FIGS. 5A and 5B, although the number of rows depends on the specific package, and the rows do not have to be identical.

While the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the scope of the invention.

Therefore, it is intended that the invention not be limited to the particular embodiments disclosed as the best mode contemplated for carrying out this invention, but that the invention will include all embodiments falling within the scope and spirit of the appended claims.

1. A stackable electrical device package comprising:
a) a first plurality of traces, said electrical device bonded to at least some of said first plurality of traces;
b) a second plurality of vertical posts attached to said first plurality of traces; and
c) encapsulation material enclosing said electrical device and sides of said first plurality of traces and sides of said second plurality of vertical posts such that bottoms of said first plurality of traces are exposed on the bottom of said semiconductor package, and tops of said vertical posts are exposed on the top of said semiconductor package.

2. The package set forth in claim 1 further including solder bumps attached to at least some of said first plurality of traces.

3. The package set forth in claim 1 further including a second stackable electrical package as set forth in claim 1 attached to the top of at least some of said second plurality of vertical posts.

4. The package set forth in claim 1 wherein one or more of said first plurality of traces has two or more of said second plurality of vertical posts attached to them.

5. A multiple electrical device package comprising:
a) a semiconductor device in a wafer having a plurality of contacts on an upper surface of said wafer;
b) a first plurality of traces attached to the top of said wafer;
c) a second plurality of vertical posts attached to said first plurality of traces;
d) an electrical device bonded to at least some of said first plurality of traces; and
e) encapsulation material enclosing said electrical device and sides of said first plurality of traces and sides of said second plurality of vertical posts such that tops of said vertical posts are exposed on the top of said semiconductor package.

6. The package set forth in claim 5 further including solder bumps attached to at least some of said second plurality of vertical posts.

7. The package set forth in claim 5 wherein one or more of said first plurality of traces has two or more of said second plurality of vertical posts attached to them.

8. A method for forming a stackable electrical device package comprising the steps of:
a) forming a first plurality of traces on a sacrificial wafer;
b) forming a second plurality of vertical posts on said first plurality of traces;
c) attaching said electrical device to at least some of said first plurality of traces; and
d) encapsulating said electrical device and sides of said first plurality of traces and sides of said second plurality of vertical posts;
e) removing said sacrificial wafer such that bottoms of said first plurality of traces are exposed on the bottom of said semiconductor package, and tops of said vertical posts are exposed on the top of said semiconductor package.

9. The method set forth in claim 8 further including attaching solder bumps to at least some of said first plurality of traces.

10. The method set forth in claim 8 further including attaching a second stackable electrical package as set forth in clam 8 to the tops of at least some of said second plurality of vertical posts.

12. The method set forth in claim 8 wherein said first plurality of traces are formed by putting down a seed layer of metal, forming a photoresist pattern on said seed metal, electroplating additional metal onto said seed layer in regions not covered by said photoresist, removing said photoresist, and etching said metal down by the thickness of said seed layer.

13. The method set forth in claim 8 wherein said second plurality of vertical posts are formed by putting down patterned photoresist and electroplating additional metal onto portions of said first plurality of traces not covered by said photoresist.

14. The method set forth in claim 8 wherein said step of encapsulating is performed using compression molding.

15. The method set forth in claim 8 wherein said step of encapsulating is performed using film assisted molding.

16. The method set forth in claim 8 further including the step of planarizing the top of the material used for the encapsulation step and tops of said second plurality of vertical posts.

17. The method set forth in claim 8 wherein said step of removing said sacrificial wafer is performed by backgrinding the wafer.

18. The method set forth in claim 8 wherein a singulation operation is performed after said sacrificial wafer is removed.

19. The method set forth in claim 18 wherein a second structure formed according to claim 8 is attached after said sacrificial wafer is removed and before said singulation operation.

20. A method for forming a multiple electrical device package comprising the steps of:
a) forming a first plurality of traces on a semiconductor wafer having a second plurality of contacts on an upper surface of said wafer, wherein at least some of said first plurality of traces are attached to at least some of said second plurality of contacts;
b) forming a third plurality of vertical posts on said first plurality of traces;
c) attaching an electrical device to at least some of said first plurality of traces; and
d) encapsulating said electrical device and sides of said first plurality of traces and sides of said second plurality of vertical posts such that tops of said vertical posts are exposed on the top of said semiconductor package.

21. The method set forth in claim 20 wherein solder balls are formed on the tops of said third plurality of vertical posts.

22. The method set forth in claim 20 wherein said first plurality of traces are formed by putting down a seed layer of metal, forming a photoresist pattern on said seed metal, electroplating additional metal onto said seed layer in regions not covered by said photoresist, removing said photoresist, and etching said metal down by the thickness of said seed layer.

23. The method set forth in claim 20 wherein said second plurality of vertical posts are formed by putting down patterned photoresist and electroplating additional metal portions of said first plurality of traces not covered by said photoresist.

24. The method set forth in claim 20 wherein said step of encapsulating is performed using compression molding.

25. The method set forth in claim 20 wherein said step of encapsulating is performed using film assisted molding.

26. The method set forth in claim 20 further including the step of planarizing the top of the material used for the encapsulation step and tops of said second plurality of vertical posts.

27. The method set forth in claim 20 wherein said semiconductor wafer is thinned by backgrinding.
